(19) United States
(12) Patent Application Publication
(10) Pub. No.: US 2021/0359045 A1
(43) Pub. Date: Nov. 18, 2021

(54) ORGANIC LIGHT-EMITTING DIODE DISPLAY PANEL AND MANUFACTURING METHOD THEREOF

(71) Applicant: Wuhan China Star Optoelectronics Semiconductor Display Technology Co., LTD., Wuhan, Hubei (CN)

(72) Inventor: Rui LU, Wuhan (CN)

(21) Appl. No.: 16/621,550

(22) PCT Filed: Oct. 10, 2019
(86) PCT No.: PCT/CN2019/110237

§ 371 Date: Dec. 11, 2019

(30) Foreign Application Priority Data
Jul. 25, 2019 (CN) 201910676901.5

(51) Int. Cl. H01L 27/32; H01L 51/52; H01L 51/56

(52) U.S. Cl. CPC H01L 27/3246; H01L 2251/301; H01L 51/56; H01L 51/5246

(57) ABSTRACT

The present disclosure provides an OLED display panel and a manufacturing method thereof. The display panel includes a base substrate; a pixel defining layer disposed on the base substrate; the pixel defining layer comprising at least one blocking unit; an anti-peeling layer covering the blocking unit; a first inorganic layer disposed on the anti-peeling layer. An adhering strength between the anti-peeling layer and the first inorganic layer is greater than an adhering strength between the blocking unit and the first inorganic layer.

### FIELD OF INVENTION

The present disclosure relates to a field of display technologies, more particularly, to a field of an organic light-emitting diode display panel and a manufacturing method thereof.

### BACKGROUND OF INVENTION

With development of display technologies, organic light-emitting diode (OLED) display panels are widely utilized due to having advantages, such as lighter weight, thinner thickness, flexibility, and wider viewing angles. Organic luminescent materials are sensitive to water and oxygen, thus even a small amount of intruded water and oxygen will make components rapidly decay and age, thereby lifetime of the display panels is affected. In order to ensure the usage life time of flexible display panels, encapsulation technology is extremely important.

Current thin-film encapsulation (TFE) layers generally adopt stacked structures of organic/inorganic film layers to block water and oxygen. In order to prevent the organic film from flowing out of the coverage area of the inorganic film, a blocking unit is generally designed to be located in a periphery of the active area (AA). However, adhering strength between the first inorganic layer and the blocking unit is weak, thereby encapsulation layers easily peel and usage life of the display panel is declined.

Therefore, an OLED display panel and a manufacturing method of the OLED display panel are required to solve the existing technical problems.

### SUMMARY OF INVENTION

The object of the present disclosure is providing an organic light-emitting diode (OLED) display panel and a manufacturing method of the OLED display panel in order to prevent encapsulation from peeling, thereby the life time of the display panel is prolonged.

To solve the above-mentioned technical problems, the present disclosure provides an OLED display panel comprising:

A base substrate.

A pixel defining layer disposed on the base substrate, the pixel defining layer comprising at least one blocking unit and a plurality of pixel defining units spaced apart from each other, an organic light-emitting layer disposed in a gap between two adjacent ones of the pixel defining units.

An anti-peeling layer covering the blocking unit.

A first inorganic layer disposed on the organic light-emitting layer, the pixel defining units, and the anti-peeling layer. An adhering strength between the anti-peeling layer and the first inorganic layer is greater than an adhering strength between the blocking unit and the first inorganic layer.

The present disclosure further provides an OLED display panel manufacturing method comprising:

Forming a pixel defining layer on a base substrate, patterning the pixel defining layer to form at least one blocking unit and to form pixel defining units spaced from each other;

Forming an anti-peeling layer on the blocking unit;

Forming an organic light-emitting layer in a gap between two adjacent ones of the pixel defining units; and

Forming a first inorganic layer on the organic light-emitting layer, the pixel defining units, and the anti-peeling layer. An adhering strength between the anti-peeling layer and the first inorganic layer is greater than an adhering strength between the blocking unit and the first inorganic layer.

The OLED display panel and the OLED display panel manufacturing method of the present disclosure add the anti-peeling layer between the blocking units and the first inorganic layer. Therefore, the adhering strength between the anti-peeling layer and the first inorganic layer is greater than the adhering strength between the blocking unit and the first inorganic layer, thereby the encapsulation layer can be prevented from peeling and the life time of the display panel is prolonged.

### DESCRIPTION OF DRAWINGS

FIG. 1 illustrates a structural diagram of a present organic light-emitting diode (OLED) display panel.

FIG. 2 illustrates a structural diagram of an OLED display panel of the present disclosure.

FIG. 3 illustrates a structural diagram of a first step of the OLED display panel manufacturing method of the present disclosure.

FIG. 4 illustrates a structural diagram of a second step of the OLED display panel manufacturing method of the present disclosure.

FIG. 4 illustrates a structural diagram of a third step of the OLED display panel manufacturing method of the present disclosure.

### DETAILED DESCRIPTION OF PREFERRED EMBODIMENTS

The following description of the various embodiments is provided with reference of drawings to illustrate specific embodiments. Directional terms mentioned in the present disclosure, such as upper, lower, front, back, left, right, inside, outside, lateral, etc., are only referring to the direction of the drawing. Therefore, the directional terms used to describe and clarify the present disclosure should not be viewed as limitations of the present disclosure. In the drawing, structurally similar elements are denoted by the same reference numbers.

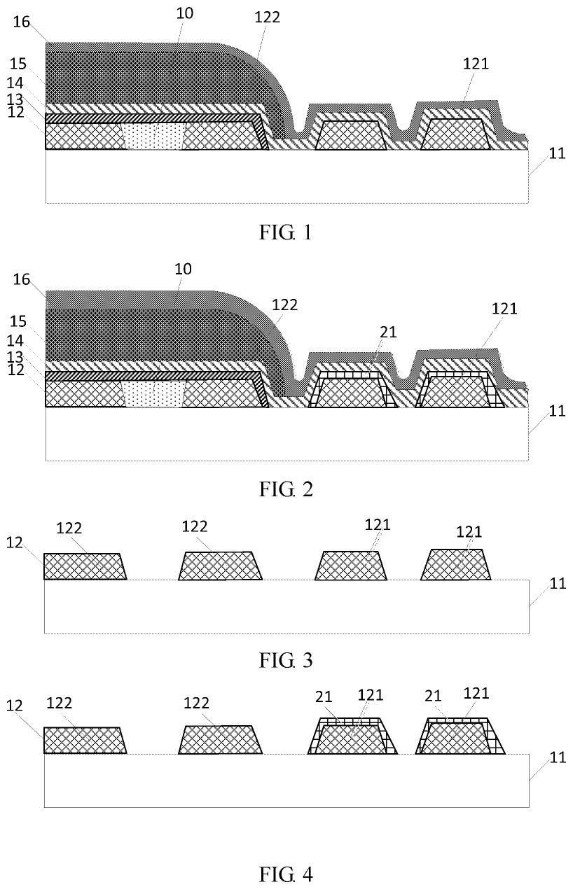

As shown in FIG. 1, the a present organic light-emitting diode (OLED) display panel includes a base substrate 11, a pixel defining layer 12, an organic light-emitting layer 10, a common layer 13, a first inorganic layer 14, an organic layer 15, and a second inorganic layer 16. The base substrate 11 includes a glass substrate and a switch array layer. The pixel defining layer 12 includes two blocking units 121 and two spaced defining pixels defining units 122. The organic light-emitting layer 10 locates at a gap between two of the adjacent pixel defining units 122. The common layer 13 is disposed on the organic light-emitting layer 10 and the pixel defining units 122. The first inorganic layer 14 is disposed on the common layer 13 and the blocking units 121. The organic layer 15 is disposed on a portion of the first inorganic layer 14. The second inorganic layer 16 is disposed on the organic layer 15.

Because the material of the organic light-emitting layer cannot resist high temperatures, the temperature of subsequent processes cannot be too high, for example not higher than 85° C. generally. As a result, the first inorganic layer 14 has to be formed at a lower temperature. The adhering strength of films formed in low temperature is worse than the films formed in high temperatures, so that the adhering strength between the first inorganic layer 14 and the blocking units 121 is weak and peeling easily occurs. The material of the existing blocking unit 121 is generally an organic polymer material. The material of the first inorganic layer is an inorganic material.

The compatibility between the different materials is worse thus the first inorganic layer 14 may peel from the blocking units 121.

Please refer to FIG. 2 to FIG. 5, where FIG. 2 illustrates a structural diagram of the OLED display panel of the present disclosure.

The OLED display panel of the present disclosure includes the base substrate 11, the pixel defining layer 12, the organic light-emitting layer 10, the anti-peeling layer 21, the first inorganic layer 14 and further includes the common layer 13, the organic layer 15, and the second inorganic layer 16.

The base substrate 11 includes a base plate and a switch array layer. The switch array layer is disposed on the base plate. The substrate may be a glass substrate or a flexible substrate. The switch array layer includes a plurality of thin film transistors.

The pixel defining layer 12 is disposed on the base substrate 11. The pixel defining layer 12 includes two blocking units 121 and two spaced defining pixels defining units 122. The organic light-emitting layer 10 is disposed at a gap between two adjacent pixel defining units 122. The material of the pixel defining layer 12 is an organic material. In an embodiment, the material of the pixel defining layer 12 may be a type of parylene material. Obviously, the number of the blocking units 121 is not limited to two, and may be one or two or more. The number of the pixel defining units 122 may be two or more.

The anti-peeling layer 21 covers on the blocking units 121. Particularly, the anti-peeling layer 21 covers on each of the blocking units 121. In order to further improve the adhering strength between the anti-peeling layer 21 and the first inorganic layer, in one of the embodiments, the material of the anti-peeling layer 21 is an inorganic material. The material of the anti-peeling layer 21 and the first inorganic layer 14 are same and are both inorganic materials. As the result, the compatibility between the layers is improved and the adhering strength between the anti-peeling layer 21 and the first inorganic layer 14 is enhanced.

In one of the embodiments, in order to further improve the adhering strength between the anti-peeling layer and the first inorganic layer, the film-forming temperature of the anti-peeling layer 21 is higher than 230° C. The actual temperature can be set according to practical requirements.

The material of the anti-peeling layer is selected from at least one of SiNx, SiOx, SiOxNy, AlOx, HfOx, and TiOx.

In one of the embodiments, a thickness of the anti-peeling layer ranges from 50 nm to 100 nm. The manufacturing method of the anti-peeling layer and the manufacturing method of the first inorganic are the same. In another embodiment, the anti-peeling layer 21 can be transparent adhesives, such as optically clear adhesive. Obviously, the materials of the anti-peeling layer 21 are not limited to the above-mentioned materials.

The first inorganic layer 14 is disposed on the organic light-emitting layer 10, the pixel defining units 122, and the anti-peeling layer 21. The adhering strength between the anti-peeling layer 21 and the first inorganic layer 14 is greater than the adhering strength between the blocking units 121 and the first inorganic layer 14.

In one of the embodiments, in order to prevent the organic light-emitting layer from damage during the manufacturing process, the film-forming temperature of the first inorganic layer 14 is low than the film-forming temperature of the anti-peeling layer 21. For example, the film-forming temperature of the first inorganic layer 14 is low than 80 degrees. The first inorganic layer 14 is utilized to block water oxygen and is formed by materials is selected from at least one of SiNx, SiOx, SiOxNy, AlOx, HfOx, and TiOx. Accompanying with FIG. 5, the manufacturing method can be plasma enhanced chemical vapor deposition (PECVD), atomic layer deposition (ALC), or pulsed laser deposition (PLD).

The common layer 13 is disposed on the organic light-emitting layer 10 and the pixel defining unit 122, and disposed below the first inorganic layer 14. The common layer 13 is utilized to enhance the light extraction rate and prevents the lower layers from damaging during subsequent process. The first inorganic layer 14 is disposed on the common layer 13 and the blocking units 121.

Please refer back to FIG. 1. The organic layer 15 is disposed on portions of the first inorganic layer 14, particularly, disposed on the first inorganic layer 14 locating in display area. The material of the organic layer 15 can be selected from acrylate, epoxy resin, hexamethyldisiloxane (HMDSO), Alucone, etc., and can be manufactured by Ink-jet printing (IJP), dispenser, plasma enhanced chemical vapor deposition (PECVD), etc.

The second inorganic layer is disposed on the organic layer. The materials of the second inorganic and the first inorganic layer 14 are the same.

In another embodiment, in order to enhance encapsulation effect, the adhering strength between the anti-peeling layer 21 and the blocking unit 121 is also greater than the adhering strength between the first inorganic layer 14 and the blocking unit 121. In another embodiment, in order to enhance the adhering strength between the anti-peeling layer and the first inorganic layer, and in order to enhance the adhering strength between the first inorganic layer and the blocking units, the film-forming temperature of the anti-peeling layer 21 is higher than 230° C. The actual temperature can be set according to practical requirements.

Because the blocking unit 121 is disposed on the anti-peeling layer 21, when the adhering strength between the anti-peeling layer and the first inorganic layer is greater than the adhering strength between the blocking unit and the first inorganic layer, the encapsulation layer can be prevented from peeling, thereby the life time of the display panel is prolonged. Furthermore, the adhesive of the anti-peeling layer is improved due to higher film-forming temperature of the anti-peeling layer, the adhering strength between the anti-peeling layer, the blocking unit and the first inorganic layer is enhanced. In addition, the materials of the anti-peeling layer and the first inorganic layer are the same thus the compatibilities between layers are enhance and the encapsulation layer is prevented from peeling.

The present disclosure further provides an OLED display panel manufacturing method comprising following steps.

Step S101: forming a pixel defining layer on a base substrate, patterning the pixel defining layer to form at least one blocking unit and to form pixel defining units spaced from each other.

As shown in FIG. 3, an entire layer of the pixel defining layer 12 is formed on the base substrate. The blocking units 121 and the pixel defining units 122 are obtained after exposing process, developing process, and other processes.

Step S102: forming an anti-peeling layer on the blocking unit.

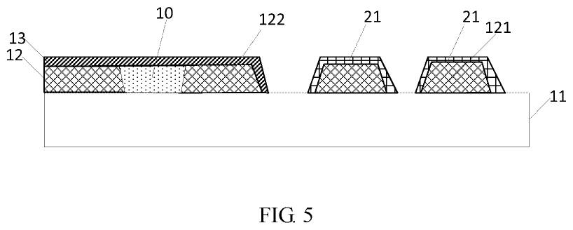

As shown in FIG. 4, for example, an entire layer of the anti-peeling layer 21 can be deposited through PECVD, ALD, PLD and other manufacturing processes. The anti-peeling layer 21 covers on the blocking unit 121 after exposing process, developing process, and other processes. The remaining areas are not covered by the anti-peeling layer 21.

Step S103: forming an organic light-emitting layer in a gap between two adjacent ones of the pixel defining units.

As shown in FIG. 5, the organic light-emitting layer 10 is formed in the gap between two of the pixel defining units 122. In one of the embodiment, organic light-emitting materials are evaporated in the gap between two of the adjacent pixel defining units 122 in order to obtain the organic light-emitting layer 10.

Step S104: forming a first inorganic layer on the organic light-emitting layer, the pixel defining units, and the anti-peeling layer.

For example, referring back to FIG. 2, the first inorganic layer 14 is formed on the organic light-emitting layer 10, the pixel defining units 122, and the anti-peeling layer 21. In addition, the first inorganic layer 14 is disposed on parts of the base substrate 11. The adhering strength between the anti-peeling layer 21 and the first inorganic layer 14 is greater than the adhering strength between the blocking units 121 and the first inorganic layer 14. An entire layer of the first inorganic layer 14 can be deposited through PECVD, ALD, PLD and other manufacturing processes. The manufacturing processes of the anti-peeling layer 21 and the first inorganic layer 14 are the same. Materials of the anti-peeling layer 21 and the first inorganic layer 14 are the same. The method further comprises sequentially forming the organic layer 15 and the second inorganic layer 16 on the first inorganic layer 14.

In another embodiment, on the basis of the above-mentioned manufacturing method, there are still following step after forming the anti-peeling layer on the blocking unit, and before forming the first inorganic layer on the organic light-emitting layer, the pixel defining units, and the anti-peeling layer.

Step S105: forming the common layer on the organic light-emitting layer and the pixel defining units.

For example, as shown in FIG. 5, the common layer 13 can be formed on the organic light-emitting layer 10 and the pixel defining units 122.

The above-mentioned step S104, i.e. forming a first inorganic layer on the organic light-emitting layer, the pixel defining units, and the anti-peeling layer, further specifically comprises the following steps.

Step S201: forming the first inorganic layer on the common layer and the anti-peeling layer.

For example, referring back to FIG. 2, the first inorganic layer 14 is formed on the common layer and the anti-peeling layer 21.

The OLED display panel and the OLED display panel manufacturing method of the present disclosure add the anti-peeling layer between the blocking units and the first inorganic layer. Therefore, the adhering strength between the anti-peeling layer and the first inorganic layer is greater than the adhering strength between the blocking unit and the first inorganic layer, thereby the encapsulation layer can be prevented from peeling and the life time of the display panel is prolonged.

To conclude, although the present disclosure has been disclosed by above-mentioned preferred embodiments, the above-mentioned preferred embodiments are not limitations to the present disclosure. Variations and modifications can be obtained by a person skilled in the art without departing from the aspect and scope of the present disclosure. Therefore, the protected scope of the present disclosure is subject to the scope defined by the claims.

What is claimed is:

1. An organic light-emitting diode (OLED) display panel, comprising:
a base substrate;
a pixel defining layer disposed on the base substrate, the pixel defining layer comprising at least one blocking unit and a plurality of pixel defining units spaced apart from each other, an organic light-emitting layer disposed in a gap between two adjacent ones of the pixel defining units;
an anti-peeling layer covering the blocking unit; and
a first inorganic layer disposed on the organic light-emitting layer, the pixel defining units, and the anti-peeling layer, wherein an adhering strength between the anti-peeling layer and the first inorganic layer is greater than an adhering strength between the blocking unit and the first inorganic layer.

2. The OLED display panel according to claim 1, wherein a material of the anti-peeling layer and a material of the first inorganic layer are same.

3. The OLED display panel according to claim 2, wherein the material of the anti-peeling layer is selected from at least one of SiNx, SiOx, SiOxNy, AlOx, HfOx, and TiOx.

4. The OLED display panel according to claim 1, wherein an adhering strength between the anti-peeling layer and the blocking unit is also greater than the adhering strength between the first inorganic layer and the blocking unit.

5. The OLED display panel according to claim 1, wherein a film-forming temperature of the anti-peeling layer is higher than 230° C.

6. The OLED display panel according to claim 1, wherein a film-forming temperature of the first inorganic layer is higher than the film-forming temperature of the anti-peeling layer.

7. The OLED display panel according to claim 1, wherein a thickness of the anti-peeling layer ranges from 50 nm to 100 nm.

8. The OLED display panel according to claim 1, wherein a manufacturing method of the anti-peeling layer and a manufacturing method of the first inorganic are same.

9. The OLED display panel according to claim 1, further comprising a common layer disposed on organic light-emitting layer and the pixel defining units, and disposed under the first inorganic layer.

10. A method for manufacturing an organic light-emitting diode (OLED) display panel, comprising:
forming a pixel defining layer on a base substrate, patterning the pixel defining layer to form at least one blocking unit and to form pixel defining units spaced from each other;
forming an anti-peeling layer on the blocking unit;
forming an organic light-emitting layer in a gap between two adjacent ones of the pixel defining units; and
forming a first inorganic layer on the organic light-emitting layer, the pixel defining units, and the anti-peeling layer; an adhering strength between the anti-peeling layer and the first inorganic layer is greater than an adhering strength between the blocking unit and the first inorganic layer.

11. The method for manufacturing the OLED display panel according to claim 10, wherein a manufacturing method of the anti-peeling layer and a manufacturing method of the first inorganic are same.

12. The method for manufacturing the OLED display panel according to claim 10, wherein after forming an anti-peeling layer on the blocking unit, before forming the first inorganic layer on the organic light-emitting layer, the pixel defining units, and the anti-peeling layer, the method for manufacturing the OLED display panel further comprises:
forming a common layer on the organic light-emitting layer and the pixel defining units;
steps of forming the first inorganic layer on the organic light-emitting layer, the pixel defining units, and the anti-peeling layer further comprises:
forming the first inorganic layer on the common layer and the anti-peeling layer.

13. The method for manufacturing the OLED display panel according to claim 10, wherein a material of the anti-peeling layer and a material of the first inorganic layer are same.

14. The method for manufacturing the OLED display panel according to claim 10, wherein a material of the anti-peeling layer is selected from at least one of SiNx, SiOx, SiOxNy, AlOx, HfOx, and TiOx.

15. The method for manufacturing the OLED display panel according to claim 10, wherein an adhering strength between the anti-peeling layer and the blocking unit is also greater than the adhering strength between the first inorganic layer and the blocking unit.

16. The method for manufacturing the OLED display panel according to claim 10, wherein a film-forming temperature of the anti-peeling layer is higher than 230° C.

17. The method for manufacturing the OLED display panel according to claim 16, wherein a film-forming temperature of the first inorganic layer is higher than the film-forming temperature of the anti-peeling layer.

18. The method for manufacturing the OLED display panel according to claim 17, wherein the film-forming temperature of the first inorganic layer is lower than 80° C.

19. The method for manufacturing the OLED display panel according to claim 10, wherein a thickness of the anti-peeling layer ranges from 50 nm to 100 nm.

20. The method for manufacturing the OLED display panel according to claim 10, wherein a material of the first inorganic layer is selected from at least one of SiNx, SiOx, SiOxNy, AlOx, HfOx, and TiOx.
